(19) United States
(12) Patent Application Publication
(10) Pub. No.: US 2024/0258383 A1
(43) Pub. Date: Aug. 1, 2024

(54) SOFT SWITCHING BY ACTIVE BACKSIDE FIELD PLATE

(71) Applicant: Analog Devices, Inc., Wilmington, MA (US)

(72) Inventors: James G. Fiorenza, Carlisle, MA (US); Daniel Piedra, Somerville, MA (US)

(21) Appl. No.: 18/413,723

(22) Filed: Jan. 16, 2024

Related U.S. Application Data
(60) Provisional application No. 63/481,741, filed on Jan. 26, 2023.

(51) Int. Cl. H01L 29/40; H01L 29/06; H01L 29/20; H01L 29/66; H01L 29/778

(52) U.S. Cl. CPC H01L 29/404; H01L 29/0603; H01L 29/2003; H01L 29/66462; H01L 29/7786

(57) ABSTRACT

This disclosure describes various techniques to use a backside field-plated GaN HEMT device as a four-terminal device. The backside field plate (BFP) may be independently biased and used to adjust the 2DEG current density in the device. By independently controlling the 2DEG channel density using the BFP, the channel current may be reduced prior to switching events, thereby enabling soft-switching using the BFP. Thus, the BFP may be used to reduce the current through the device during switching events to reduce the power loss and stress on the device that may occur during hard-switching.

### CLAIM OF PRIORITY

This application claims the benefit of priority of U.S. Provisional Patent Application Ser. No. 63/481,741, titled “SOFT SWITCHING BY ACTIVE BACKSIDE FIELD PLATE” to James G. Fiorenza et al., filed on Jan. 26, 2023, the entire contents of which being incorporated herein by reference.

### FIELD OF THE DISCLOSURE

This document pertains generally, but not by way of limitation, to semiconductor devices, and more particularly, to techniques for constructing gallium nitride devices.

### BACKGROUND

Gallium nitride (GaN) based semiconductors offer several advantages over other semiconductors as the material of choice for fabricating the next generation of transistors, or semiconductor devices, for use in both high voltage and high frequency applications. GaN based semiconductors, for example, have a wide bandgap that enable devices fabricated from these materials to have a high breakdown electric field and to be robust to a wide range of temperatures. The two-dimensional electron gas (2DEG) channels formed by GaN based heterostructures generally have high electron mobility, making devices fabricated using these structures useful in power-switching and amplification systems.

### SUMMARY OF THE DISCLOSURE

This disclosure describes various techniques to use a backside field-plated GaN HEMT device as a four-terminal device. The backside field plate (BFP) may be independently biased and used to adjust the 2DEG current density in the device. By independently controlling the 2DEG channel density using the BFP, the channel current may be reduced prior to switching events, thereby enabling soft-switching using the BFP. Thus, the BFP may be used to reduce the current through the device during switching events to reduce the power loss and stress on the device that may occur during hard-switching.

In some aspects, this disclosure is directed to a compound semiconductor heterostructure transistor device comprising: a substrate; a first semiconductor material layer formed over the substrate; a second semiconductor material layer formed over the first semiconductor material layer to form a compound semiconductor heterostructure having a two-dimensional electron gas (2DEG) channel, wherein the 2DEG channel is more conductive than either the first semiconductor material layer or the second semiconductor material layer; a drain electrode electrically coupled with the 2DEG channel; a source electrode electrically coupled with the 2DEG channel; a gate electrode formed over the second semiconductor material layer; a backside field plate disposed at least partially within the substrate, the backside field plate configured to modulate an electric field between the gate electrode and the drain electrode of the transistor device; and a backside field plate electrode electrically coupled with the backside field plate, wherein the backside field plate electrode is configured to be electrically coupled with a voltage supply that is independent of a gate voltage, a drain voltage, and a source voltage.

In some aspects, this disclosure is directed to a method of forming a compound semiconductor heterostructure transistor device, the method comprising: forming a first semiconductor material layer over a substrate; forming a second semiconductor material layer over the first semiconductor material layer to form a compound semiconductor heterostructure having a two-dimensional electron gas (2DEG) channel, wherein the 2DEG channel is more conductive than either the first semiconductor material layer or the second semiconductor material layer; electrically coupling a drain electrode with the 2DEG channel; electrically coupling a source electrode with the 2DEG channel; forming a gate electrode over the first semiconductor material layer; forming a backside field plate, wherein the backside field plate is disposed at least partially within the substrate, the backside field plate extending laterally from a region underlying the source electrode of the transistor device to a region between the gate electrode and the drain electrode of the transistor device, the backside field plate configured to modulate an electric field between the gate electrode and the drain electrode of the transistor device; forming a backside field plate electrode electrically coupled with the backside field plate; and electrically coupling the backside field plate electrode with a voltage supply that is independent of a gate voltage, a drain voltage, and a source voltage.

In some aspects, this disclosure is directed to a compound semiconductor heterostructure transistor device comprising: a substrate; a first semiconductor material layer formed over the substrate; a second semiconductor material layer formed over the first semiconductor material layer to form a compound semiconductor heterostructure having a two-dimensional electron gas (2DEG) channel, wherein the 2DEG channel is more conductive than either the first semiconductor material layer or the second semiconductor material layer; a drain electrode electrically coupled with the 2DEG channel; a source electrode electrically coupled with the 2DEG channel; a gate electrode formed over the second semiconductor material layer; a backside field plate disposed at least partially within the substrate, the backside field plate extending laterally from a region underlying the source electrode of the transistor device to a region between the gate electrode and the drain electrode of the transistor device, the backside field plate configured to modulate an electric field between the gate electrode and the drain electrode of the transistor device; a backside field plate electrode electrically coupled with the backside field plate, wherein the backside field plate electrode is configured to be electrically coupled with a voltage supply that is independent of a gate voltage, a drain voltage, and a source voltage; and a top-side field plate formed over the second semiconductor material layer.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a graph depicting the power loss of a switch in a hard-switching state.

FIG. 2 is a graph depicting the power loss of a switch in a soft-switching state.

FIG. 3 depicts a cross-sectional diagram of an example of a GaN transistor device that may implement various techniques of this disclosure.

FIG. 4 depicts a cross-sectional diagram of another example of a GaN transistor device that may implement various techniques of this disclosure.

FIG. 5 illustrates an aspect of the subject matter in accordance with one embodiment.

FIG. 6 depicts various examples of graphs of the gate voltage, backside field plate voltage, and drain current of a transistor device using various techniques of this disclosure.

FIG. 7 illustrates a flow diagram of an example of a method of forming a compound semiconductor heterostructure transistor device.

### DETAILED DESCRIPTION

As used in this disclosure, a GaN-based compound semiconductor material may include a chemical compound of elements including GaN and one or more elements from different groups in the periodic table. Such chemical compounds may include a pairing of elements from group 13 (i.e., the group comprising boron (B), aluminum (Al), gallium (Ga), indium (In), and thallium (Tl)) with elements from group 15 (i.e., the group comprising nitrogen (N), phosphorus (P), arsenic (As), antimony (Sb), and bismuth (Bi)). Group 13 of the periodic table may also be referred to as Group III and group 15 as Group V. In an example, a semiconductor device may be fabricated from GaN and aluminum indium gallium nitride (AlInGaN).

Heterostructures described herein may be formed as AlN/GaN/AlN hetero-structures, InAlN/GaN heterostructures, AlGaN/GaN heterostructures, or heterostructures formed from other combinations of group 13 and group 15 elements. These heterostructures may form a two-dimensional electron gas (2DEG) at the interface of the compound semiconductors that form the heterostructure, such as the interface of GaN and AlGaN. The 2DEG may form a conductive channel of electrons that may be controllably depleted, such as by an electric field formed by a buried layer of p-type material disposed below the channel. The conductive channel of electrons that may also be controllably enhanced, such as by an electric field formed by a gate terminal disposed above the channel to control a current through the semiconductor device. Semiconductor devices formed using such conductive channels may include high electron mobility transistor (HEMT) devices.

The present inventors have recognized that a backside field-plated GaN HEMT device may be used as a four-terminal device. The present inventors have also recognized that the backside field plate (BFP) may be independently biased and used to adjust the 2DEG current density in the device. By independently controlling the 2DEG channel density using the BFP, the channel current may be reduced prior to switching events, thereby enabling soft-switching using the BFP. Thus, the BFP may be used to reduce the current through the device during switching events to reduce the power loss and stress on the device that may occur during hard-switching.

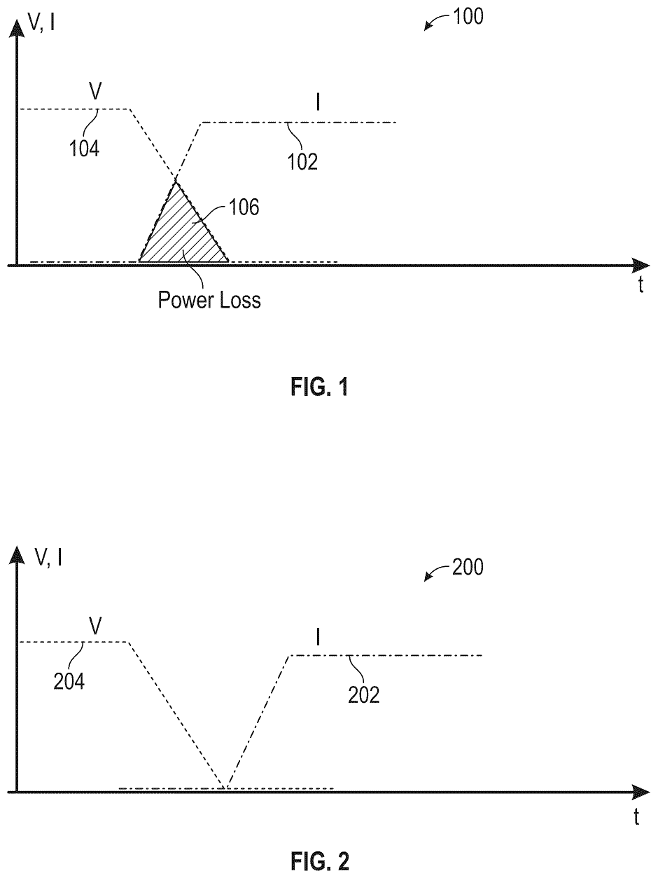

FIG. 1 is a graph depicting the power loss of a switch in a hard-switching state. In the graph 100, the x-axis represents time (t) and the y-axis represents both voltage (V) and current (I). The current is represented by line 102 and the voltage is represented by line 104.

Switches in power management circuits may be used in a hard-switching state, where the current through the switch and the voltage across the switch are simultaneously non-zero during the switching events, such as shown in the power loss region 106 of FIG. 1. Hard-switching may cause unwanted power loss and stress on the device, which may harm the device and negatively affect reliability.

FIG. 2 is a graph depicting the power loss of a switch in a soft-switching state. In the graph 200, the x-axis represents time (t) and the y-axis represents both voltage (V) and current (I). The current is represented by line 202 and the voltage is represented by line 204. In soft-switching or zero voltage switching, the current and voltage have minimal overlap in the “high” state, which results in less power loss, as shown in FIG. 2. Traditionally, soft-switching is accomplished by adjusting the gate-switching timing.

As described below and in accordance with this disclosure, a backside field-plated GaN HEMT device may be used as a four-terminal device. The backside field plate (BFP) may be independently biased and used to adjust the 2DEG current density in the device so as to reduce the channel current prior to switching events, thereby enabling soft-switching using the BFP.

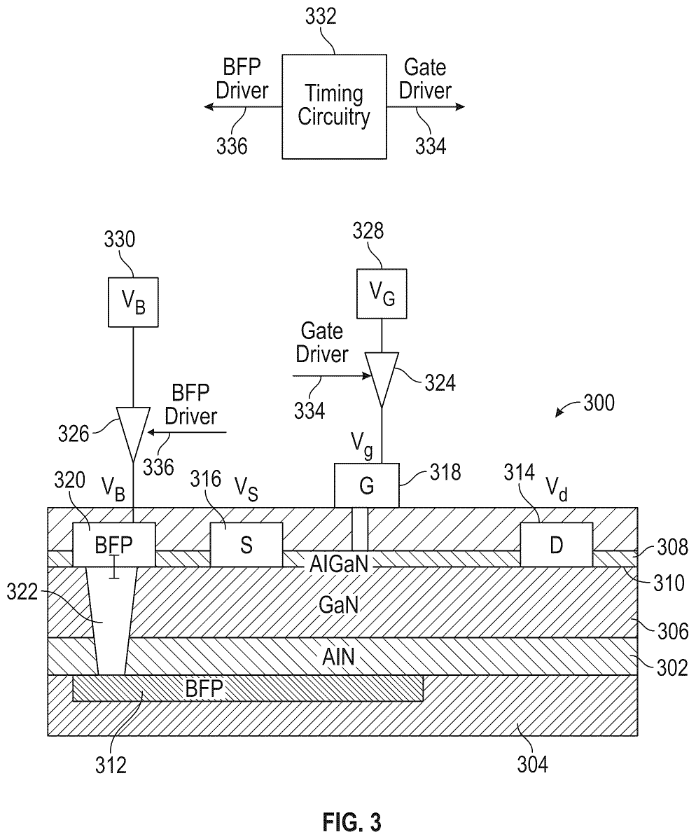

FIG. 3 depicts a cross-sectional diagram of an example of a GaN transistor device that may implement various techniques of this disclosure. The transistor device 300 in FIG. 3 includes a first semiconductor material layer 302, such as aluminum nitride (AlN), formed over a substrate 304, such as silicon carbide substrate (SiC).

In some examples, the first semiconductor material layer 302 forms part of an optional nucleation layer. A gallium nitride (GaN) epitaxial layer (hereinafter, “epi layer”) may be grown over the nucleation layer. The GaN epi is then grown on the nucleation layer by growing a second semiconductor material layer 306 (or channel layer), such as a layer of unintentionally doped GaN, over the first semiconductor material layer 302. Then, a third semiconductor material layer 308 (or barrier layer), such as a layer of aluminum gallium nitride (AlGaN), is grown over the second semiconductor material layer 306, to form a compound semiconductor heterostructure having a 2DEG channel 310 at the interface of the second semiconductor material layer 306 and the third semiconductor material layer 308. The 2DEG channel 310 is more conductive than either the second semiconductor material layer 306 or the third semiconductor material layer 308.

The transistor device 300 includes a backside field plate 312 (“BFP”) in the substrate 304 to control or reduce gate-drain electric fields at the surface of the transistor, thereby enabling the transistor to operate at higher voltages while reducing charge trapping and breakdown effects. In some examples, the backside field plate 312 is formed by bonding. In other examples, the backside field plate 312 is a heavily doped buried implant region in the substrate 304. For example, the substrate 304 is implanted with a p-type dopant and the dopant is activated to form a buried activated implanted region (hereinafter, “implanted region” or “buried implant region”). In another example, the buried implant region is formed by implanting the substrate with a p-type dopant and an n-type dopant and activating each dopant to form an activated p-type region and an activated n-type region. In an example, the implanted region is masked and patterned to have an indicated geometry or shape.

A drain electrode 314 and a source electrode 316 are electrically coupled to the 2DEG channel 310. A gate electrode 318 is formed over the third semiconductor material layer 308. The backside field plate 312 is disposed at least partially within the substrate 304 and extends laterally from a region underlying the source electrode 316 of the transistor device 300 to a region between the gate electrode 318 and the drain electrode 314. The backside field plate 312 is configured to modulate an electric field between the gate electrode 318 and the drain electrode 314 of the transistor device.

In some examples, a backside field plate electrode, e.g., BFP electrode 320, is electrically coupled with the backside field plate, such as using a via 322. Operation of the backside field plate may minimize electric field peaks that may cause charge trapping, device breakdown, and other reliability or performance issues. In an example, the distance between the backside field plate 312 and the 2DEG channel 310 (e.g., the thickness or height of the combined nucleation layer and channel layer) is between 200 and 400 nanometers (nm).

A BFP electrode 320 is electrically coupled with the backside field plate 312, such as using a via 322. Using the techniques of this disclosure, a BFP bias voltage V_{B} is applied to the backside field plate 312 using the BFP electrode 320. The bias voltage V_{B} is a voltage supply that is independent of a gate voltage V_{G}, a source voltage V_{S}, and a drain voltage V_{D}. The bias voltage V_{B} modulates the current density in the 2DEG channel 310 by shifting the threshold voltage. For example, by bringing the BFP bias voltage V_{B} low before the gate voltage V_{G} is reduced to switch off the device, the amount of charge in the 2DEG channel 310 may be reduced. Because the backside field plate 312 may independently control the 2DEG current density, the 2DEG current density may be ramped down by the backside field plate 312 at the switching times, resulting in soft switching. In some examples, the bias voltage V_{B} is between about 5 volts and about 100 volts, and more particularly between about 10 volts and 40 volts.

The backside field plate 312 acts like a second gate to control the conduction of the 2DEG channel 310 by lowering the on-resistance and increasing efficiency. By biasing the backside field plate 312 separately from the gate electrode 318, the drain current is boosted, e.g., a 10%-30% increase, independently of a gate voltage V_{G} applied to the gate electrode 318.

The gate electrode 318 and the BFP electrode 320 may be coupled with corresponding driver circuitry. For example, the gate electrode 318 may be coupled with a gate driver 324 and the BFP electrode 320 may be coupled with a BFP driver 326. A voltage supply V_{G} 328 may be coupled with the gate driver 324 and a voltage supply V_{B} 330 may be coupled with the BFP driver 326.

Timing circuitry 332 may be used to control the timing between corresponding drivers associated with the gate electrode 318 and the BFP electrode 320. The timing circuitry 332 may output timing signals 334, 336 to the gate driver 324 and the BFP driver 326, respectively.

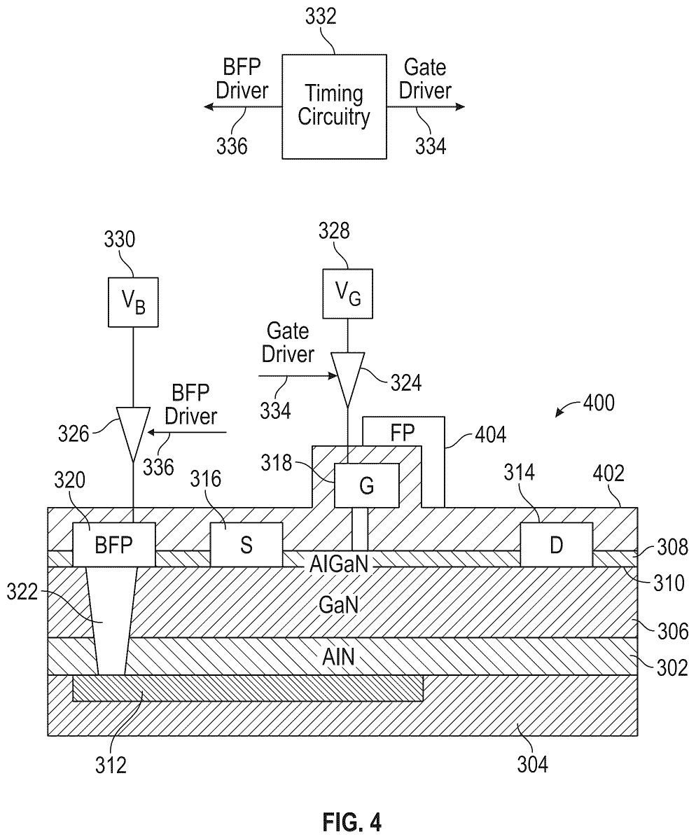

FIG. 4 depicts a cross-sectional diagram of another example of a GaN transistor device that may implement various techniques of this disclosure. The transistor device 400 of FIG. 4 includes some features that are similar to those shown and described above with respect to FIG. 3 and similar reference numbers are used for such features. For brevity, those features will not be described again in detail.

The transistor device 400 of FIG. 4 further includes a passivation layer 402, such as silicon dioxide, formed over the third semiconductor material layer 308, such as to help inhibit or prevent oxidation and/or contamination. A top-side field plate 404 (which may also be referred to as a front-side field plate) may be used to help inhibit or prevent electrical breakdown between the gate electrode 318 and the drain electrode 314. Voltage may be computed as the product of the size of an electric field between two points and the distance between the points. While, for a given implementation of the semiconductor device, the distance between the gate electrode 318 and the drain electrode 314 may be fixed, the top-side field plate 404 may spatially distribute the electric field generated between the two electrodes over a conductor having a large area, such as to reduce the flux of the electric field through any given point, such as to reduce the voltage between the gate electrode 318 and the drain electrode 314. Such distribution of the electric field may enable higher voltages to be used at the gate electrode 318 or the drain electrode 314 before breakdown, such as to help increase the power density of the semiconductor device.

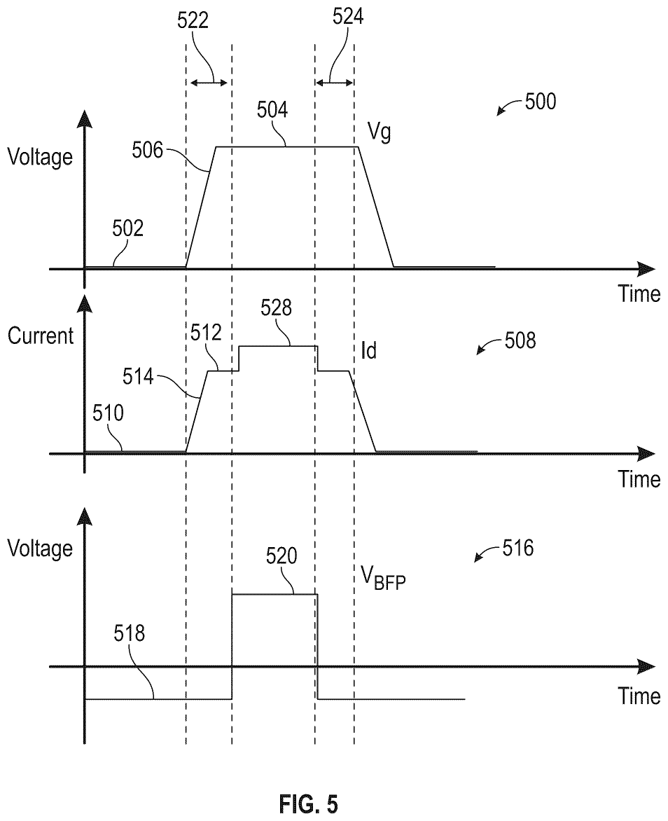

FIG. 5 depicts various examples of graphs of the gate voltage, backside field plate voltage, and drain current of a transistor device using various techniques of this disclosure. The top graph 500 depicts a gate voltage applied to a gate electrode of a transistor device, such as V_{G} 328 applied to the gate electrode 318 of FIG. 3. The gate voltage increases from a first gate voltage 502 to a constant second gate voltage 504 over a ramping portion 506 over which the voltage is changing.

The middle graph 508 depicts a drain current through a drain electrode of a transistor device using the techniques of this disclosure, such as the drain electrode 314 of FIG. 3. The drain current increases from a first drain current 510 to a constant second drain current 512 over a ramping portion 514 over which the drain current is changing.

The bottom graph 516 depicts a backside field plate voltage applied to a backside field plate electrode, such as V_{B} 330 applied to the BFP electrode 320 of FIG. 3. The backside field plate voltage increases from a first backside field plate voltage 518 to a constant second backside field plate voltage 520.

In some examples, the timing circuitry, such as the timing circuitry 332 of FIG. 3, controls the gate voltage and the backside field plate voltage to be applied at different times. For example, the timing circuitry may control application of the first gate voltage 502 to the gate electrode to turn on the transistor device. Then, after a time 522 and while applying the first gate voltage 502, the timing circuitry may control application of the second backside field plate voltage 520 to the backside field plate electrode. In some examples, the time 522 is equal to or greater than the time it takes the first gate voltage 502 to reach the constant second gate voltage 504 voltage, so that the second backside field plate voltage 520 is applied with the gate voltage is constant.

As seen in FIG. 5, the application of the second backside field plate voltage 520 results in increased drain current, shown as a constant third drain current 528. Thus, these techniques may boost the drain current.

Similarly, the second backside field plate voltage 520 may be removed before the second gate voltage 504 is removed. For example, while the timing circuitry 332 is controlling application of the second gate voltage 504, the timing circuitry 332 controls the reduction or removal of the second backside field plate voltage 520 applied to the backside field plate electrode. Then, after reducing or removing the second backside field plate voltage 520, such as a time 524, the timing circuitry 332 controls the reduction or removal of the second gate voltage 504 applied to the gate electrode so as to turn off the transistor device.

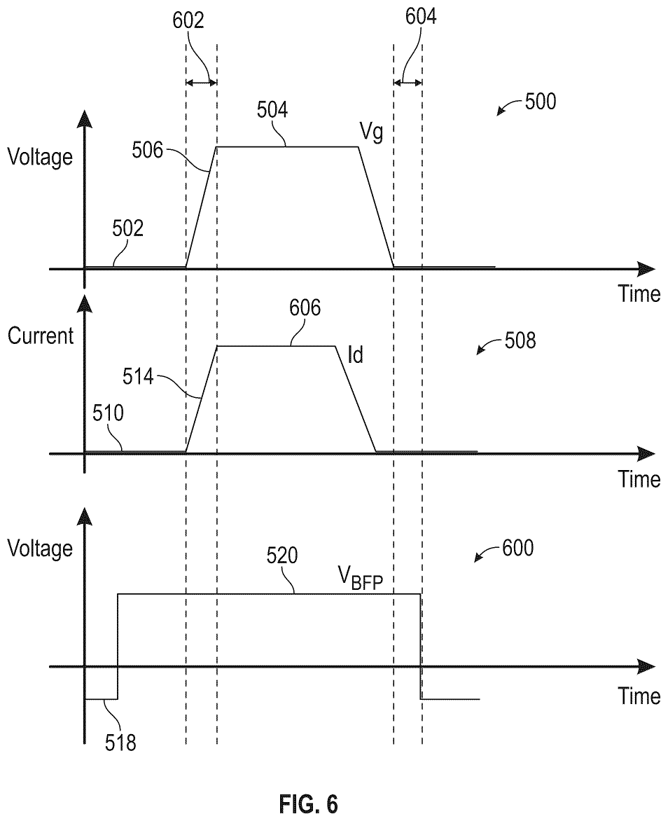

FIG. 6 depicts various examples of graphs of the gate voltage, backside field plate voltage, and drain current of a transistor device using various techniques of this disclosure. The graphs in FIG. 6 include some features that are similar to those shown and described above with respect to FIG. 5 and similar reference numbers are used for such features. For brevity, those features will not be described again in detail.

In FIG. 6, the top graph 500 and the middle graph 508 are similar to the top graph 500 and the middle graph 508 in FIG. 5. The bottom graph 600 depicts a backside field plate voltage applied to a backside field plate electrode, such as V_{B} 330 applied to the BFP electrode 320 of FIG. 3. The backside field plate voltage increases from a first backside field plate voltage 518 to a constant second backside field plate voltage 520.

In some examples, the timing circuitry, such as the timing circuitry 332 of FIG. 3, controls the gate voltage and the backside field plate voltage to be applied at different times. For example, the timing circuitry controls the application of the second backside field plate voltage 520 to the backside field plate electrode. Then, after a time 602 and while applying the second backside field plate voltage 520, the timing circuitry 332 controls the application of the second gate voltage 504 to the gate electrode to turn on the transistor device.

As seen in FIG. 6, the application of the second backside field plate voltage 520 results in a constant drain current 606, which is elevated throughout the duration of the application of the second backside field plate voltage 520. Thus, these techniques boost the drain current 606 above a level that would occur without the application of the second backside field plate voltage 520, e.g., the level of the drain current 512 in FIG. 5.

Similarly, the second gate voltage 504 may be removed before the second backside field plate voltage 520 is removed. While applying second backside field plate voltage 520 to the backside field plate electrode, the timing circuitry 332 controls a reduction or removal of the second gate voltage 504 applied to the gate electrode to turn off the transistor device. Then, after reducing or removing the second gate voltage 504, such as a time 604, reducing or removing the second backside field plate voltage 520 applied to the backside field plate electrode.

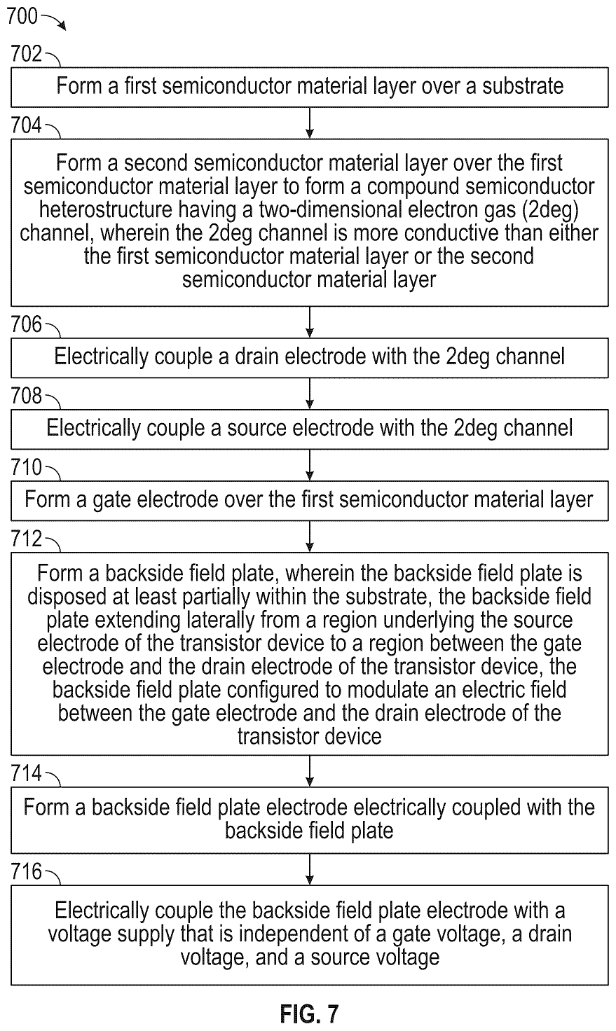

FIG. 7 illustrates a flow diagram of an example of a method of forming a compound semiconductor heterostructure transistor device. At block 702, the method 700 includes forming a first semiconductor material layer over a substrate.

At block 704, the method 700 includes forming a second semiconductor material layer over the first semiconductor material layer to form a compound semiconductor heterostructure having a two-dimensional electron gas (2DEG) channel, wherein the 2DEG channel is more conductive than either the first semiconductor material layer or the second semiconductor material layer.

At block 706, the method 700 includes electrically coupling a drain electrode with the 2DEG channel.

At block 708, the method 700 includes electrically coupling a source electrode with the 2DEG channel.

At block 710, the method 700 includes forming a gate electrode over the first semiconductor material layer.

At block 712, the method 700 includes forming a backside field plate, wherein the backside field plate is disposed at least partially within the substrate, the backside field plate extending laterally from a region underlying the source electrode of the transistor device to a region between the gate electrode and the drain electrode of the transistor device, the backside field plate configured to modulate an electric field between the gate electrode and the drain electrode of the transistor device.

At block 714, the method 700 includes forming a backside field plate electrode electrically coupled with the backside field plate.

At block 716, the method 700 includes electrically coupling the backside field plate electrode with a voltage supply that is independent of a gate voltage, a drain voltage, and a source voltage.

### VARIOUS NOTES

Each of the non-limiting claims or examples described herein may stand on its own, or may be combined in various permutations or combinations with one or more of the other examples.

The above-detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer-readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read-only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. A compound semiconductor heterostructure transistor device comprising:
a substrate;
a first semiconductor material layer formed over the substrate;
a second semiconductor material layer formed over the first semiconductor material layer to form a compound semiconductor heterostructure having a two-dimensional electron gas (2DEG) channel, wherein the 2DEG channel is more conductive than either the first semiconductor material layer or the second semiconductor material layer;
a drain electrode electrically coupled with the 2DEG channel;
a source electrode electrically coupled with the 2DEG channel;
a gate electrode formed over the second semiconductor material layer;
a backside field plate disposed at least partially within the substrate, the backside field plate configured to modulate an electric field between the gate electrode and the drain electrode of the transistor device; and
a backside field plate electrode electrically coupled with the backside field plate, wherein the backside field plate electrode is configured to be electrically coupled with a voltage supply that is independent of a gate voltage, a drain voltage, and a source voltage.

2. The compound semiconductor heterostructure transistor device of claim 1, wherein the backside field plate electrode and the gate electrode are configured to be electrically coupled with timing circuitry, and wherein the timing circuitry is configured for:
applying a first voltage to the gate electrode to turn on the transistor device; and
after a first time and while applying the first voltage, applying a second voltage to the backside field plate electrode.

3. The compound semiconductor heterostructure transistor device of claim 2, wherein the first time is equal to or greater than a time it takes the first voltage to reach a constant voltage.

4. The compound semiconductor heterostructure transistor device of claim 2, wherein the second voltage is between about 5 volts and about 100 volts.

5. The compound semiconductor heterostructure transistor device of claim 1, wherein the backside field plate electrode and the gate electrode are configured to be electrically coupled with timing circuitry, and wherein the timing circuitry is configured for:
while applying a first voltage to the gate electrode, reducing or removing a second voltage applied to the backside field plate electrode; and
after reducing or removing the second voltage, reducing or removing the first voltage applied to the gate electrode to turn off the transistor device.

6. The compound semiconductor heterostructure transistor device of claim 1, wherein the backside field plate electrode and the gate electrode are configured to be electrically coupled with timing circuitry, and wherein the timing circuitry is configured for:
applying a first voltage to the backside field plate electrode; and
after a first time and while applying the first voltage, applying a second voltage to the gate electrode to turn on the transistor device.

7. The compound semiconductor heterostructure transistor device of claim 1, wherein the backside field plate electrode and the gate electrode are configured to be electrically coupled with timing circuitry, and wherein the timing circuitry is configured for:
while applying a first voltage to the backside field plate electrode, reducing or removing a second voltage applied to the gate electrode to turn off the transistor device; and
after reducing or removing the second voltage, reducing or removing the first voltage applied to the backside field plate electrode.

8. The compound semiconductor heterostructure transistor device of claim 1, wherein the backside field plate electrode is electrically coupled with the backside field plate using a via.

9. The compound semiconductor heterostructure transistor device of claim 1, comprising:
a field plate formed over the second semiconductor material layer.

10. The compound semiconductor heterostructure transistor device of claim 1, comprising:
a third semiconductor material layer formed between the substrate and the first semiconductor material layer.

11. A method of forming a compound semiconductor heterostructure transistor device, the method comprising:
forming a first semiconductor material layer over a substrate;
forming a second semiconductor material layer over the first semiconductor material layer to form a compound semiconductor heterostructure having a two-dimensional electron gas (2DEG) channel, wherein the 2DEG channel is more conductive than either the first semiconductor material layer or the second semiconductor material layer;
electrically coupling a drain electrode with the 2DEG channel;
electrically coupling a source electrode with the 2DEG channel;
forming a gate electrode over the first semiconductor material layer;
forming a backside field plate, wherein the backside field plate is disposed at least partially within the substrate, the backside field plate extending laterally from a region underlying the source electrode of the transistor device to a region between the gate electrode and the drain electrode of the transistor device, the backside field plate configured to modulate an electric field between the gate electrode and the drain electrode of the transistor device;
forming a backside field plate electrode electrically coupled with the backside field plate; and
electrically coupling the backside field plate electrode with a voltage supply that is independent of a gate voltage, a drain voltage, and a source voltage.

12. The method of claim 11, comprising:
electrically coupling the backside field plate electrode and the gate electrode with timing circuitry;
applying a first voltage to the gate electrode to turn on the transistor device; and
after a first time and while applying the first voltage, applying a second voltage to the backside field plate electrode.

13. The method of claim 12, wherein the first time is equal to or greater than a time it takes the first voltage to reach a constant voltage.

14. The method of claim 11, comprising:
electrically coupling the backside field plate electrode and the gate electrode with timing circuitry:
applying a first voltage to the backside field plate electrode; and
after a first time and while applying the first voltage, applying a second voltage to the gate electrode to turn on the transistor device.

15. The method of claim 11, comprising:
forming a field plate over the second semiconductor material layer.

16. The method of claim 11, comprising:
while applying a first voltage to the gate electrode, reducing or removing a second voltage applied to the backside field plate electrode; and
after reducing or removing the second voltage, reducing or removing the first voltage applied to the gate electrode to turn off the transistor device.

17. The method of claim 11, comprising:
applying a first voltage to the backside field plate electrode; and
after a first time and while applying the first voltage, applying a second voltage to the gate electrode to turn on the transistor device.

18. The method of claim 11, comprising:
while applying a first voltage to the backside field plate electrode, reducing or removing a second voltage applied to the gate electrode to turn off the transistor device; and
after reducing or removing the second voltage, reducing or removing the first voltage applied to the backside field plate electrode.

19. A compound semiconductor heterostructure transistor device comprising:
a substrate;
a first semiconductor material layer formed over the substrate;
a second semiconductor material layer formed over the first semiconductor material layer to form a compound semiconductor heterostructure having a two-dimensional electron gas (2DEG) channel, wherein the 2DEG channel is more conductive than either the first semiconductor material layer or the second semiconductor material layer;
a drain electrode electrically coupled with the 2DEG channel;
a source electrode electrically coupled with the 2DEG channel;
a gate electrode formed over the second semiconductor material layer;
a backside field plate disposed at least partially within the substrate, the backside field plate extending laterally from a region underlying the source electrode of the transistor device to a region between the gate electrode and the drain electrode of the transistor device, the backside field plate configured to modulate an electric field between the gate electrode and the drain electrode of the transistor device;
a backside field plate electrode electrically coupled with the backside field plate, wherein the backside field plate electrode is configured to be electrically coupled with a voltage supply that is independent of a gate voltage, a drain voltage, and a source voltage; and
a top-side field plate formed over the second semiconductor material layer.

20. The compound semiconductor heterostructure transistor device of claim 19, wherein the backside field plate electrode and the gate electrode are configured to be electrically coupled with timing circuitry, and wherein the timing circuitry is configured for:
applying a first voltage to the gate electrode to turn on the transistor device; and
after a first time and while applying the first voltage, applying a second voltage to the backside field plate electrode.
